(19) United States
(12) Patent Application Publication
(10) Pub. No.: US 2018/0166620 A1
(43) Pub. Date: Jun. 14, 2018

(54) ELECTRONIC DEVICE

(71) Applicant: TOYODA GOSEI CO., LTD., Kiyosu-shi (JP)

(72) Inventors: Eiki KAWANO, Kiyosu-shi (JP); Norifumi HATTORI, Kiyosu-shi (JP)

(21) Appl. No.: 15/834,132

(22) Filed: Dec. 7, 2017

(30) Foreign Application Priority Data
Dec. 9, 2016 (JP) 2016-239523

(51) Int. Cl. H01L 33/64; H01L 21/66; H01L 23/495; H01L 21/48; H01L 33/62

(52) U.S. Cl. CPC H01L 33/647; H01L 22/32; H01L 23/49503; H01L 23/49551; H01L 23/49558; H01L 2933/0066; H01L 23/49575; H01L 21/4839; H01L 21/4842; H01L 33/62; H01L 23/49568

(57) ABSTRACT

An electronic device includes: a first element which generates heat, and a second element which generates heat; a lead frame which includes: a first portion on which the first element is mounted; a second portion on which the second element is mounted; and a high-heat resistance portion between the first portion and the second portion; and a resin portion which covers a part of the lead frame.

### CROSS-REFERENCE TO RELATED APPLICATION (S)

This application is based upon and claims the benefit of priority from prior Japanese patent application No. 2016-239523, filed on Dec. 9, 2016, the entire contents of which are incorporated herein by reference.

### BACKGROUND

The present invention relates to an electronic device.

In recent years, reduction in size of LED light source modules has been advanced. In the LED light source modules, a plurality of parts (heat-generating parts), which generate heat, including LEDs, are mounted on a substrate. When a distance between the heat-generating parts is shortened due to the reduction in size of the modules, there is a possibility that influence of heat may occur between the heat-generating parts through a lead frame electrically connecting the heat-generating parts. That is, while separately generating heat, a plurality of heat-generating parts also receive heat from other heat-generating parts mounted in proximity through the lead frame, and there is a possibility that any of the plurality of heat-generating parts in proximity to each other may be in a state where it is difficult to be cooled down. Such a problem that the plurality of heat-generating parts in proximity to each other cause thermal adverse influence on each other is not limited to the LED light source modules, and it is also a problem that may occur in a small electronic device in which a plurality of heat-generating parts are mounted on a substrate.

JP-A-2004-063688 discloses a technique intended to increase thermal resistance from a lead to a package and reduce an amount of heat dissipation from the lead to the package by reducing a cross sectional area (width) of a second lead portion which is a heat transfer path from the lead to the package (refer to Paragraph [0042] etc. of JP-A-2004-063688).

The technique described in JP-A-2004-063688 is intended to suppress transfer of heat generated between the lead and the package. Namely, in the technique, the transfer of heat through the lead frame between the plurality of heat-generating parts mounted on the substrate in the package is not suppressed, and the influence of heat between the plurality of heat-generating parts is not suppressed.

### SUMMARY

It is therefore an object of the invention to provide an electronic device capable of effectively suppressing influence of heat through a lead frame between a plurality of heat-generating parts mounted on a substrate of the electronic device.

In order to achieve the object, according to an aspect of the invention, there is provided an electronic device comprising: a first element which generates heat, and a second element which generates heat; a lead frame which includes: a first portion on which the first element is mounted; a second portion on which the second element is mounted; and a high-heat resistance portion between the first portion and the second portion; and a resin portion which covers a part of the lead frame.

### BRIEF DESCRIPTION OF THE DRAWINGS

FIGS. 1A is a plan view of a light emitting device according to one embodiment of the present invention, and FIG. 1B is a plan view showing a substrate of the light emitting device in FIG. 1A.

FIG. 2 is an elevation view of the light emitting device according to one embodiment.

FIG. 3 is a plan view showing lead frames of the light emitting device according to one embodiment.

FIGS. 4A and 4B transparently show a resin portion. FIG. 4A is a cross-sectional view showing a cross section of the substrate in FIG. 1B taken along a line IVA-IVA and FIG. 4B is a cross-sectional view showing across section of the substrate in FIG. 1B taken along a line IVB-IVB.

FIG. 5 is an explanatory view for explaining a method of producing the light emitting device according to one embodiment.

FIG. 6 is another explanatory view for explaining the method of producing the light emitting device according to one embodiment.

FIGS. 7A and 7B are further explanatory views for explaining the method of producing the light emitting device according to one embodiment.

### DETAILED DESCRIPTION OF EXEMPLARY EMBODIMENTS

Hereinafter, a light emitting device will be described as an example of an electronic device according to one embodiment of the present invention. However, an electronic device to which the present invention can be applied is not limited to the light emitting device.

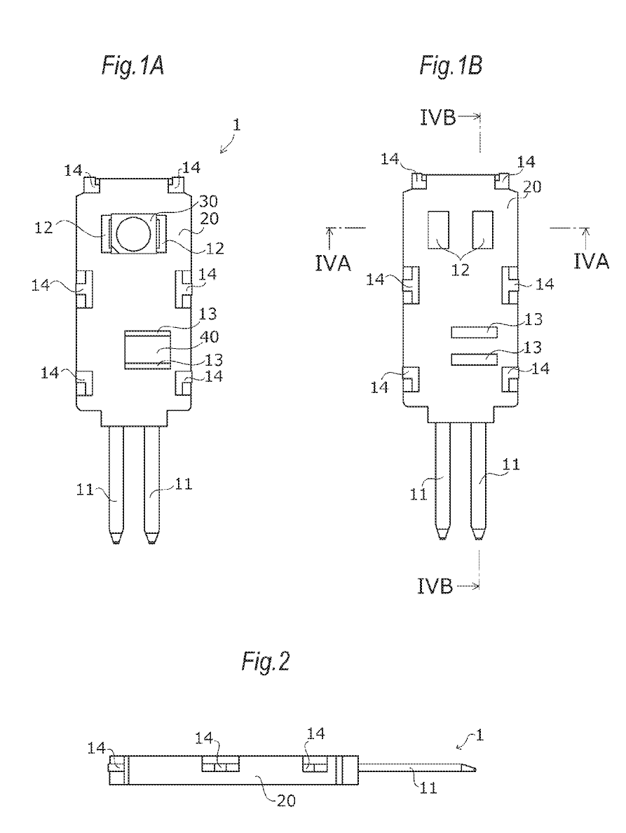

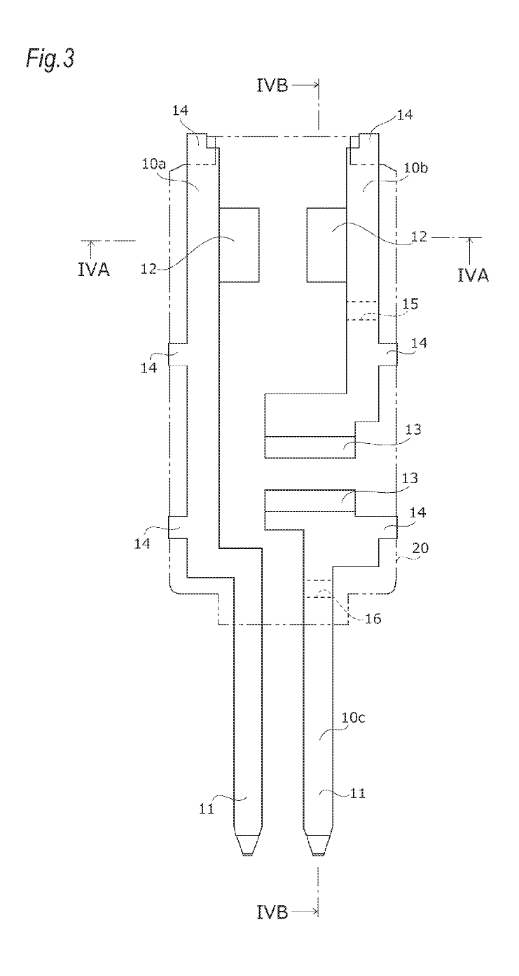

FIG. 1A is a plan view of a light emitting device 1 according to one embodiment of the present invention, and FIG. 2 is an elevation view of a light emitting device according to one embodiment. The light emitting device 1 of this embodiment can be used for, for example, a foot light in a vehicle compartment of an automobile, a lighting device in a console box, a lighting device in a glove box, and the like. The light emitting device 1 includes a plurality of (three in the illustrated example) metal lead frames 10a, 10b, 10c shown in FIG. 3, and a resin portion 20 made of synthetic resin which partially covers the lead frames 10a, 10b, 10c. A substrate shown in FIG. 1B in which the lead frames 10a, 10b, 10c and the resin portion 20 are integrated is formed by performing insert molding in a manner that predetermined portions of the lead frames 10a, 10b, 10c are covered with molten resin. In FIG. 3, a contour of the resin portion 20 covering the lead frames 10a, 10b, 10c is indicated by a two-dot chain line. The light emitting device 1 further includes an LED 30 and a resistance 40 which are mounted on the substrate.

The LED 30 and the resistance 40 are elements mounted on the substrate of the light emitting device 1, and are taken as representatives of elements which generate heat. Other elements, and configurations for mounting the elements on the substrate are not shown or described. As shown in FIG. 1A to FIG. 3, a plurality of portions of the lead frames 10a, 10b, 10c, which are not covered with the resin portion 20 but exposed, function as: terminal portions 11 to which a mating device is to be connected; LED mounting pads 12 on which the LED 30 is soldered; resistance mounting pads 13 on which the resistance 40 is soldered; and test pads 14 to which probes are to be applied when testing whether an insulating property of the substrate is ensured, respectively. A portion, of the resin portion 20, around the test pad 14 has a shape such that the probe can be applied to the test pad 14 without interference between the probe and the resin portion 20 when the probe is applied to the test pad 14.

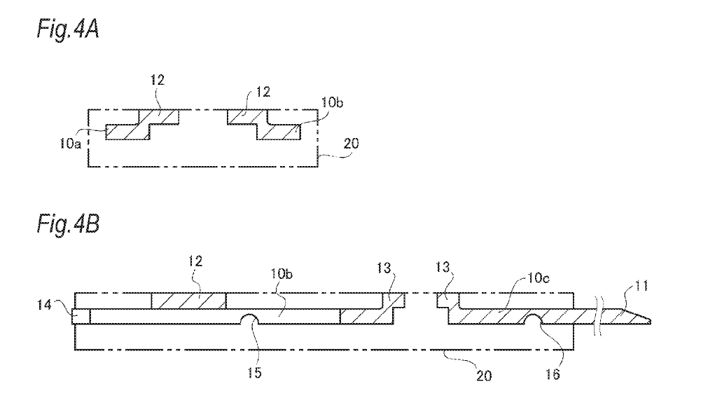

FIG. 4A is a cross-sectional view showing an IVA-IVA cross section of the substrate in FIG. 1B, and FIG. 4B is cross-sectional view showing an IVB-IVB cross section of the substrate in FIG. 1B. FIGS. 4A and 4B transparently show the resin portion 20. In FIGS. 4 and 4B, the contour of the resin portion 20 is indicated by a two-dot chain line. As shown in FIG. 4A, the lead frames 10a, 10b respectively include the LED mounting pad 12, and a portion adjacent to the LED mounting pad 12 is bent by half punching. With such a structure, the LED mounting pad 12 is lifted to a location which is one-step higher than other portions of the lead frames 10a, 10b. The resin portion 20 is formed such that a surface of the LED mounting pad 12 lifted in such a manner is exposed from a surface of the resin portion 20. Similarly, as shown in FIG. 4B, the lead frames 10b, 10c respectively include the resistance mounting pad 13, and a portion adjacent to the resistance mounting pad 13 is bent by half punching. Accordingly, the resistance mounting pad 13 is lifted to a location which is one-step higher than other portions of the lead frames 10b, 10c. The resin portion 20 is formed such that a surface of the resistance mounting pad 13 lifted in such a manner is exposed from the surface of the resin portion 20.

Since the lead frames 10a, 10b, 10c are bent such that the portions including the LED mounting pads 12 and the resistance mounting pads 13 are lifted to the locations which are one-step higher than other portions respectively, when the resin portion 20 is formed by insert molding, a flow path of the molten resin on a side opposite to a lifting direction (a lower side in FIGS. 4A and 4B) can be enlarged, and the moldability of the resin portion 20 is improved. Since the resin portion 20 is formed such that the surfaces of the LED mounting pads 12 and the resistance mounting pads 13 are exposed from the surface of the resin portion 20 in a state where the LED mounting pads 12 and the resistance mounting pads 13 are lifted one-step higher, a thickness of the resin portion 20 can be increased and rigidity of the substrate can be improved as compared with a case where all of the lead frames 10a, 10b, 10c are formed in a flat plate shape and surfaces thereof are exposed from the surface of the resin portion 20.

As will be understood from FIG. 3 and FIG. 4B, the lead frame 10b includes the LED mounting pad 12 and the resistance mounting pad 13, and both the LED 30 and the resistance 40 are mounted on the single lead frame 110b. The LED 30 and the resistance 40 are elements which generate heat, and are mounted on the single lead frame 10b such that the LED 30 and the resistance 40 are in proximity to each other, so that there is a possibility that influence of heat through the lead frame 10b between the LED 30 and the resistance 40 may occur. That is, each of the LED 30 and the resistance 40 generates heat, and receives heat from the other through the lead frame 10b, and there is a possibility that both of the LED 30 and the resistance 40 may be in a state in which it is difficult to be cooled down.

Therefore, in the light emitting device 1 according to this embodiment, as shown in FIG. 4B, a recess portion 15 is formed on a lower surface of the lead frame 10b in the drawing (a surface opposite to a surface on which the element is mounted), and the portion where the recess portion 15 is formed is a thin portion of the lead frame 10b. Accordingly, an area of a cross section of the lead frame 10b orthogonal to a direction of heat transfer between the LED 30 and the resistance 40 is reduced. Thereby, the portion of the lead frame 10b where the recess portion 15 is formed functions as a high-heat resistance portion. Since the high-heat resistance portion thus configured has an effect of suppressing the transfer of heat between the LED 30 and the resistance 40, the occurrence of the influence of heat between the LED 30 and the resistance 40 can be suppressed. For example, the recess portion 15 has a partial cylindrical shape having an axis orthogonal to a longitudinal direction (or a direction of the heat transfer) of the lead frame 10b. Therefore, a cross-sectional shape of the recess portion 15 in the longitudinal direction of the lead frame 10b has an arc-shaped contour. Consequently, as compared with a case where a cross-sectional shape of the recess portion 15 is a corner with a rectangular shape and the like, the molten resin easily flows along a surface of the recess portion 15 when the resin portion 20 is formed by the insert molding, and the moldability of the resin portion 20 is improved. In particular, the possibility that air remains in the recess portion 15 is reduced. In addition, since the resin is thus filled inside the recess portion 15, a decrease in strength of the lead frame 10b due to the formation of the recess portion 15 is not a problem.

As shown in FIG. 4(B), a recess portion 16 similar to the recess portion 15 is formed on a lower surface of the lead frame 10c (a surface opposite to a surface on which the resistance 40 is mounted), and the portion where the recess portion 16 is formed is a thin portion of the lead frame 10c. Accordingly, an area of a cross section of the lead frame 10c orthogonal to a direction in which heat is transferred to a mating device which is to be connected to the terminal portion 11 from the resistance 40 is reduced. Thereby, the portion of the lead frame 10c where the recess portion 16 is formed functions as a high-heat resistance portion. The high-heat resistance portion thus configured has an effect of suppressing transfer of heat generated by the resistance 40 to the mating device. For example, the recess portion 16 has a partial cylindrical shape having an axis orthogonal to a longitudinal direction (or a direction of the heat transfer) of the lead frame 10c. Therefore, a cross-sectional shape of the recess portion 16 in the longitudinal direction of the lead frame 10c has an arc-shaped contour, and has the same advantages as in the case of the recess portion 15. The recess portion 16 is formed in a position which is inside the resin portion 20 and in the vicinity of a base end of the terminal portion 11. Accordingly, a decrease in strength of the lead frame 10c due to the formation of the recess portion 16 can be compensated by the resin portion 20. In FIG. 3, the positions where the recess portions 15, 16 are formed are indicated by dotted lines.

(Production, Method, for Substrate)

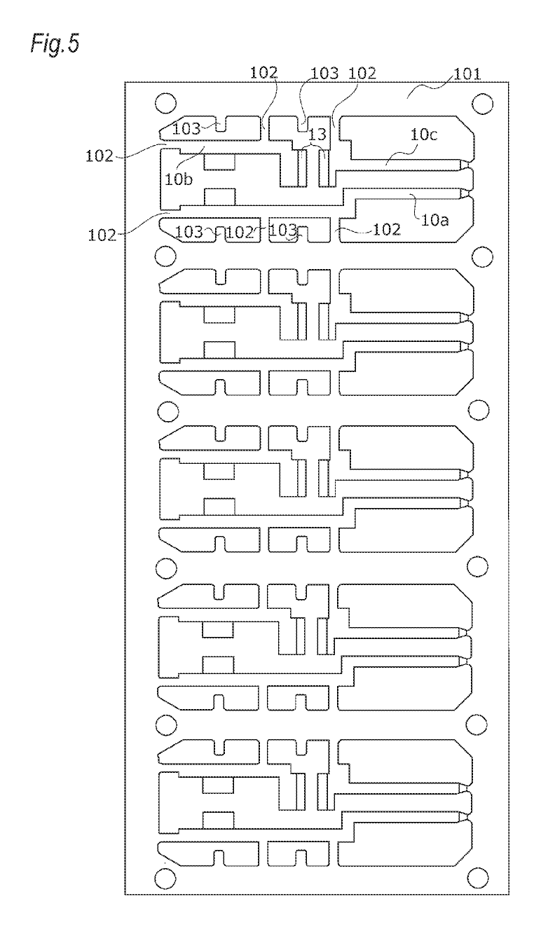

Next, an overview of a method of producing a substrate according to this embodiment will be described with reference to FIGS. 5 to 7B. FIG. 5 shows a state where the plurality of lead frames 10a, 10b, 10c corresponding to the plurality of substrates (five in the illustrated example) are integrally connected to a metal frame body 101 via tie bars 102 (lead frame connecting portions). In the state shown in FIG. 5, portions of the LED mounting pads 12 of the lead frames 10a, 10b and portions of the resistance mounting pads 13 of the lead frames 10b, 10c have already been lifted one-step higher than other portions by half punching. Reference numeral 103 denotes a holding portion extending from the frame body 101.

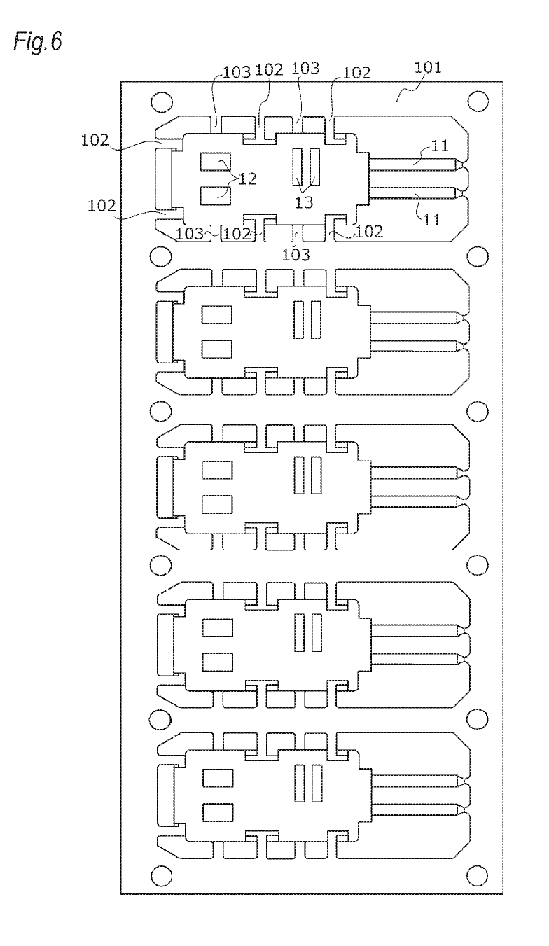

Next, an integral body of the frame body 101 and the plurality of lead frames 10a, 10b, 10c shown in FIG. 5 is set in a molding die (not shown), and insert molding is performed with the molten resin. Therefore, as shown in FIG. 6, a portion of the lead frames 10a, 10b, 10c, excluding the terminal portions 11, the surfaces of the LED mounting pads 12, the surfaces of the resistance mounting pads 13, and portions to be the test pads 14, is covered with the resin portion 20, and is integrated with the frame body 101 by the tie bars 102 and the holding portions 103.

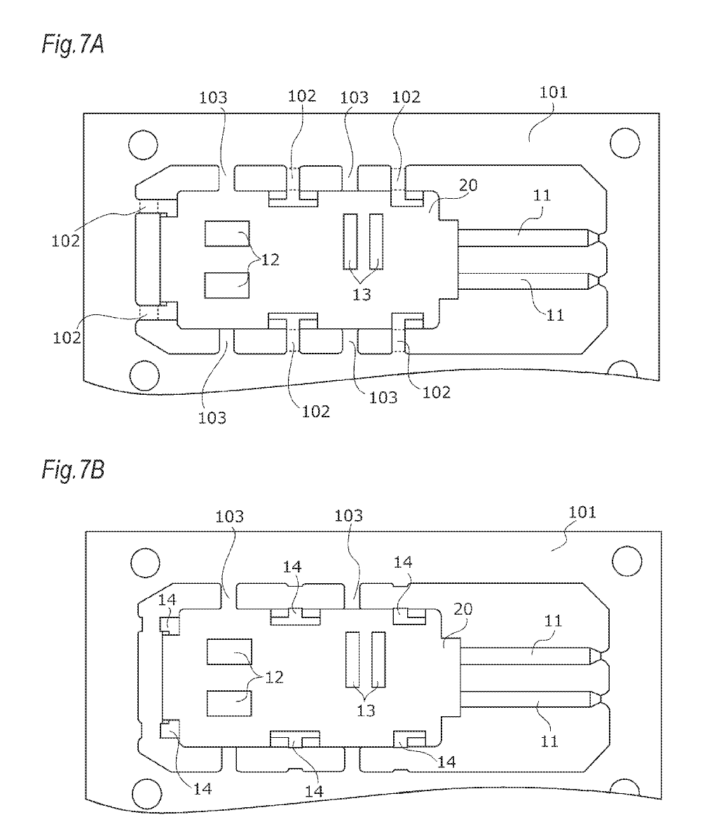

FIG. 7A shows one of the substrates of FIG. 6. Next, the tie bars 102 are cut and separated at portions indicated by dotted lines in FIG. 7A. Accordingly, as shown in FIG. 7B, the substrate is held on the frame body 101 by the holding portion 103. As shown in FIGS. 7A and 7B, the test pads 14 are formed on predetermined portions of the substrate by cutting and separating the tie bars 102.

As illustrated above, since in the light emitting device 1 of this embodiment, the recess portion 15 is formed in a portion between the LED mounting pad 12 and the resistance mounting pad 13 of the lead frame 10b for connecting the LED 30 and the resistance 40 which are the heating elements, the portion of the lead frame 10b where the recess portion 15 is formed, i.e., the thin portion, functions as the high-heat resistance portion for suppressing the transfer of heat between the LED 30 and the resistance 40. Accordingly, since the occurrence of the influence of heat between the LED 30 and the resistance 40 can be suppressed, the LED 30 and the resistance 40 can be arranged in proximity to each other. This contributes to the reduction in size of the light emitting device 1.

Since the portions configuring the LED mounting pads 12 of the lead frames 10a, 10b and the portions configuring the resistance mounting pads 13 of the lead frames 10b, 10c are lifted one-step higher than other portions, the flow path of the molten resin on the lower side thereof is enlarged so that the moldability of the resin portion 20 can be improved, and the thickness of the resin portion 20 is increased so that the rigidity of the substrate can be improved. Therefore, this contributes to the reduction in size of the light emitting device 1.

Further, since the test pads 14 are formed by cutting and separating the tie bars 102 for connecting the lead frames 10a, 10b, 10c and the frame body 101, the reduction in size of the light emitting device 1 can be achieved and the production cost of the light emitting device 1 can be reduced, as compared with a case where the test pads 14 are formed independent of the tie bars 102.

In the above embodiments, the recess portions 15, 16 are described as each having a partial cylindrical shape having an axis orthogonal to the longitudinal direction (or the direction of the heat transfer) of the lead frames 10b, 10c, but the present invention is not limited thereto, as long as the recess portion has a shape which can form a thin portion in the lead frames 10b, 10c.

The present invention is not limited to the description of the embodiments of the invention and modifications thereof in any way. Various modifications are also included in the present invention as long as those skilled in the art can easily conceive without departing from the scope of the claims.

According to an aspect of the invention, there is provided an electronic device comprising: a first element which generates heat, and a second element which generates heat; a lead frame which includes: a first portion on which the first element is mounted; a second portion on which the second element is mounted; and a high-heat resistance portion between the first portion and the second portion; and a resin portion which covers a part of the lead frame. According to such a configuration, since the lead frame includes the high-heat resistance portion between the first portion on which the first element is mounted and the second portion on which the second element is mounted, the transfer of heat through the lead frame between the first element and the second element can be suppressed by the high-heat resistance portion. As a result, occurrence of the influence of heat between the first element and the second element which are heat-generating parts can be effectively suppressed.

The high-heat resistance portion of the lead frame may be a thin portion. In this case, a desired high-heat resistance portion can be formed on the lead frame by a relatively simple method.

A cross section of the thin portion may include a contour portion having an arc shape. In this case, when the resin portion is formed by insert molding, the molten resin easily flows along a peripheral surface of the thin portion, and the moldability of the resin portion is improved.

Portion adjacent to the first portion and the second portion of the lead frame may be bent, so that the first portion and the second portion are exposed from the resin portion. In this case, when the resin portion is formed by insert molding, a flow path of the molten resin is enlarged so that the moldability of the resin portion can be improved, and the thickness of the resin portion is increased so that the rigidity of the resin portion can be improved.

The lead frame may include a terminal portion, and a portion which is in the vicinity of a base end of the terminal portion and is covered with the resin portion may include a thin portion. In this case, the transfer of heat from the element generating the heat to a mating device to which the terminal portion is connected can be suppressed. Since the thin portion is covered with the resin portion, the decrease in strength due to thinning of the terminal portion can be compensated by the resin portion.

According to an aspect of the invention, there is also provided a method of producing the electronic device in which the lead frame includes a test pad exposed from the resin portion, the method comprising: covering the lead frame with the resin portion so that the test pad is exposed in a state where the lead frame is connected to a lead frame connecting portion; and separating the lead frame connecting portion. Thereby, since the test pad is formed by separating the lead frame connecting portion, the reduction in size of the electronic device can be achieved and the production process of the electronic device can be simplified as compared with a case where the test pad is formed independent of the lead frame connecting portion.

What is claimed is:

1. An electronic device comprising:
a first element which generates heat, and a second element which generates heat;
a lead frame which includes: a first portion on which the first element is mounted; a second portion on which the second element is mounted; and a high-heat resistance portion between the first portion and the second portion; and
a resin portion which covers a part of the lead frame.

2. The electronic device according to claim 1, wherein the high-heat resistance portion of the lead frame is a thin portion.

3. The electronic device according to claim 2, wherein a cross section of the thin portion includes a contour portion having an arc shape.

4. The electronic device according to claim 1, wherein portions adjacent to the first portion and the second portion of the lead frame are bent, so that the first portion and the second portion are exposed from the resin portion.

5. The electronic device according to claim 1, wherein the lead frame includes a terminal portion, and a portion which is in the vicinity of a base end of the terminal portion and is covered with the resin portion includes a thin portion.

6. A method of producing the electronic device according to claim 1, the electronic device in which the lead frame includes a test pad exposed from the resin portion, the method comprising:
covering the lead frame with the resin portion so that the test pad is exposed in a state where the lead frame is connected to a lead frame connecting portion; and
separating the lead frame connecting portion.
